(19) United States
(12) Patent Application Publication
(10) Pub. No.: US 2019/0244846 A1
(43) Pub. Date: Aug. 8, 2019

(54) TRANSFER DEVICE

(71) Applicant: Chunghwa Picture Tubes, LTD., Taoyuan City (TW)

(72) Inventors: Wen-Jiunn Hsieh, New Taipei City (TW); Cheng-Min Liao, Taoyuan City (TW); Wen-Tse Tseng, Taoyuan City (TW)

(73) Assignee: Chunghwa Picture Tubes, LTD., Taoyuan City (TW)

(21) Appl. No.: 15/968,759

(22) Filed: May 2, 2018

(30) Foreign Application Priority Data
Feb. 6, 2018 (CN) 201810117400.9

(51) Int. Cl. H01L 21/677; H01L 21/683; H01L 33/00

(52) U.S. Cl. CPC H01L 21/67721; H01L 33/00; H01L 21/683

(57) ABSTRACT

A transfer device for transferring a plurality of micro LED dies is provided. The transfer device includes a carrier plate, a plurality of deformable components, and a plurality of transfer heads. The plurality of deformable components are disposed on the carrier plate. The plurality of transfer heads are respectively disposed on the plurality of deformable components. Each of the transfer heads includes a plurality of micro protrusions arranged in an array on a side away from the corresponding one deformable component. Deformation of the deformable components leads to deformation of the transfer heads, such that a number of the micro protrusions in contact with the micro LED dies is decreased. Accordingly, the transfer device can easily release the micro LED dies.

### CROSS-REFERENCE TO RELATED APPLICATION

This application claims the priority benefit of China application serial no. 201810117400.9, filed on Feb. 6, 2018. The entirety of the above-mentioned patent application is hereby incorporated by reference herein and made a part of this specification.

### BACKGROUND OF THE INVENTION

### Field of the Invention

The disclosure relates to LED display manufacturing equipment, and in particular, to a transfer device for micro LED dies.

### Description of Related Art

In recent years, organic light-emitting diode (OLED) display panels have gradually replaced liquid-crystal display (LCD) panels in the mobile communication device markets and have been slowly penetrating the large-screen TV markets. Although a color saturation, a response speed, and a contrast of OLED display panels are all more desirable than those of mainstream LCD panels, a lifetime of products is not comparable to that of the current mainstream displays.

With the OLED display panels incurring relatively high manufacturing costs, micro LED displays have come to attract attention from many manufacturers. Micro LED displays show optical performance comparable to the OLED display technology and further exhibit advantages of low power consumption and a long lifetime of materials. However, the manufacturing costs of micro LED displays are still higher than those of the OLED displays in the current techniques. One of the main reasons is that, in the manufacturing technique of the micro LED displays, manufactured micro LED dies are directly transferred onto a driving circuit plate through a die transfer method. Although such high-volume transfer technique exhibits potential advantages in manufacturing large-size products, there are bottlenecks to overcome in terms of the relevant manufacturing techniques as well as equipment.

The pick up method used in the current die transfer techniques includes methods involving an electrostatic force, an electromagnetic force, a van der Waals force, an adhesive material, or self-assembly. The electrostatic force method requires a higher external voltage, so there are high risks of arcing and dielectric breakdown. Although the self-assembly transfer technique has developmental potential in rapid die transfer, it requires a high-precision control technique for a fluid evaporation rate. Moreover, control difficulty is present in large-area manufacturing and may result in failed die transfers. When the van der Waals force is exploited to adsorb dies, adsorption and desorption of dies depend on a rate at which an elastomer macromolecular stamp is contacted with the dies. Therefore, precise control over actuations of the stamp is required, and a success rate of transfer is not high.

### SUMMARY OF THE INVENTION

The embodiments of the invention provide a transfer device for transferring micro LED dies. By using the transfer device, a success rate of transferring the micro LED dies is high.

An embodiment of the invention provides a transfer device including a carrier plate, a plurality of deformable components, and a plurality of transfer heads. The plurality of deformable components are disposed on the carrier plate. The plurality of transfer heads are respectively disposed on the plurality of deformable components. Each of the transfer heads includes a plurality of micro protrusions arranged in an array on a side away from the corresponding one deformable component.

In another embodiment of the invention, each of the deformable components of the transfer device is adapted to be deformed due to an influence of light, heat, or electricity, and the deformed deformable components protrude towards a direction away from the carrier plate.

In another embodiment of the invention, the deformable components of the transfer device include a first material layer and a second material layer. The first material layer is disposed on the carrier plate and has a first coefficient of thermal expansion. The second material layer is disposed on the first material layer and has a second coefficient of thermal expansion. The second coefficient of thermal expansion is larger than the first coefficient of thermal expansion.

In another embodiment of the invention, the deformable components of the transfer device include an alloy formed of at least two metals having different resistivities.

In another embodiment of the invention, the deformable components of the transfer device include a titanium layer and a first nickel layer. The titanium layer is disposed on the carrier plate. The first nickel layer is disposed on the titanium layer.

In another embodiment of the invention, the deformable components of the transfer device further include a second nickel layer. The titanium layer is sandwiched between the first nickel layer and the second nickel layer.

In another embodiment of the invention, the deformable components of the transfer device include macromolecules having azobenzene group in a molecular structure.

In another embodiment of the invention, the plurality of micro protrusions of the transfer device include a plurality of pillars spaced apart from each other.

In another embodiment of the invention, the carrier plate of the transfer device includes a plurality of carrying bumps spaced apart from each other, and the plurality of deformable components are respectively disposed on the plurality of carrying bumps.

In another embodiment of the invention, each of the carrying bumps is located within an area of the corresponding one deformable component.

The transfer device of the embodiments of the invention picks up the micro LED dies by using the transfer heads. When the transfer device is to release the micro LED dies, the deformable components are deformed, which leads to bending of the transfer heads, such that a number of the micro protrusions of the transfer heads in contact with the micro LED dies is decreased. When the number of the micro protrusions in contact with the micro LED dies is decreased to the extent that a van der Waals force cannot be sufficiently generated, the micro LED dies are naturally released from the transfer heads and successfully transferred onto a target (e.g., a driving circuit plate). Accordingly, a success rate of transferring the micro LED dies is high, and the micro LED dies can be rapidly transferred in large quantities.

### BRIEF DESCRIPTION OF THE DRAWINGS

The accompanying drawings are included to allow further understanding of the embodiments of invention, and the drawings are incorporated into the specification and form a part of the specification. The drawings illustrate the embodiments of the invention, and the drawings and the description together are used to interpret the principles of the invention.

FIG. 1 is a cross-sectional schematic diagram illustrating a transfer device according to an embodiment of the invention.

FIG. 2 is a top-view schematic diagram illustrating a transfer head according to an embodiment of the invention.

FIG. 3A to FIG. 3E illustrate a process of transferring a plurality of micro LED dies by using a transfer device according to an embodiment of the invention.

FIG. 4 illustrates a cross-section of a deformable component according to an embodiment of the invention.

FIG. 5 illustrates a cross-section of a deformable component according to another embodiment of the invention.

FIG. 6 illustrates a cross-section of a deformable component according to another embodiment of the invention.

FIG. 7 is a cross-sectional schematic diagram illustrating a deformable component according to another embodiment of the invention.

### DESCRIPTION OF THE EMBODIMENTS

Reference will now be made in detail to the exemplary embodiments of the invention, examples of which are illustrated in the accompanying drawings. Wherever possible, the same reference numbers are used in the drawings and the description to refer to the same or like parts.

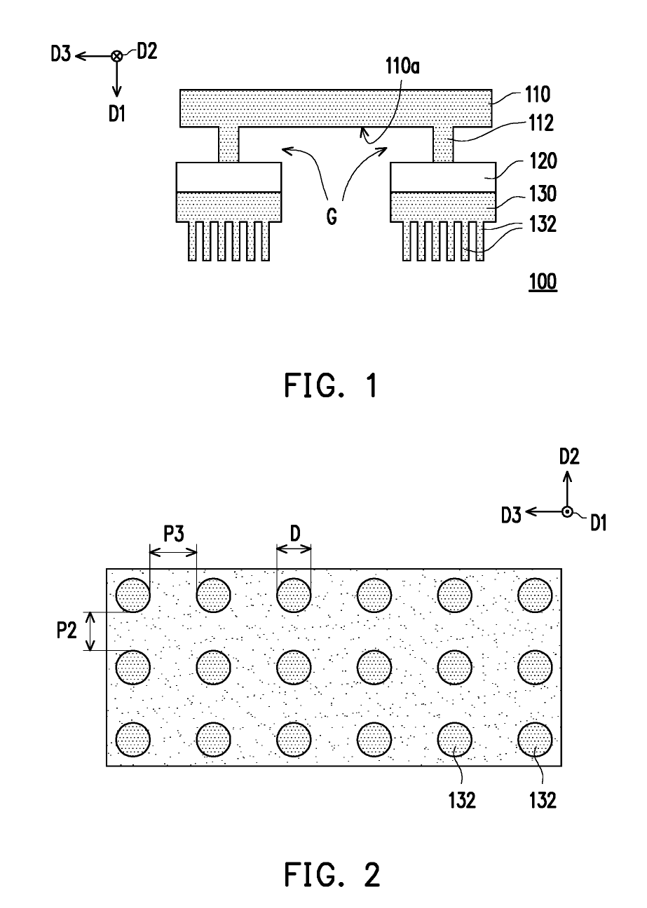

FIG. 1 is a cross-sectional schematic diagram illustrating a transfer device according to an embodiment of the invention. Referring to FIG. 1, a transfer device 100 includes a carrier plate 110, a plurality of deformable components 120, and a plurality of transfer heads 130. The plurality of deformable components 120 are disposed on the carrier plate 110. In the present embodiment, the carrier plate 110 is selectively an elastomer. For example, a material of the carrier plate 110 includes polysiloxane, or more specifically, polydimethyl siloxane, but the invention is not limited hereto.

For example, in the present embodiment, the carrier plate 110 selectively includes a plurality of carrying bumps 112 spaced apart from each other, and the plurality of deformable components 120 are respectively disposed on the plurality of carrying bumps 112. The carrier plate 110 includes a working surface 110a configured to face micro LED dies (not illustrated). The carrying bump 112 is located within an area of the deformable component 120. By disposing the deformable components 120 on the carrying bumps 112, a space G is present between the deformable components 120 and the working surface 110a of the carrier plate 110 to allow the deformable components 120 to stretch when they are deformed. However, the invention is not limited hereto. In other embodiments, the space G may also be maintained between the deformable components 120 and the working surface 110a of the carrier plate 110 by using other components, or the deformable components 120 may also be directly disposed on the working surface 110a of the carrier plate 110.

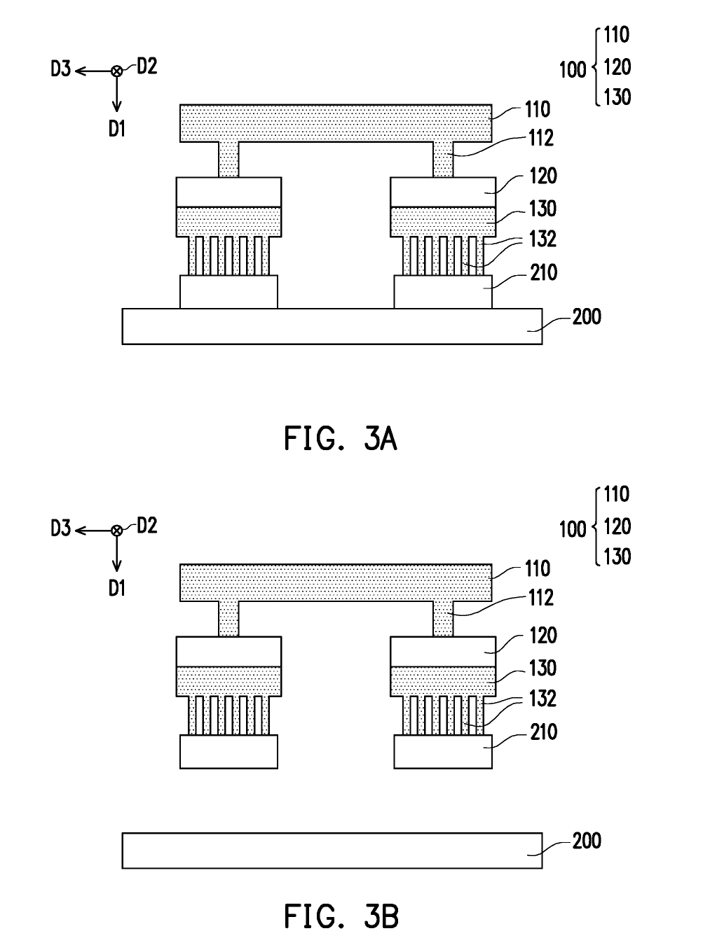

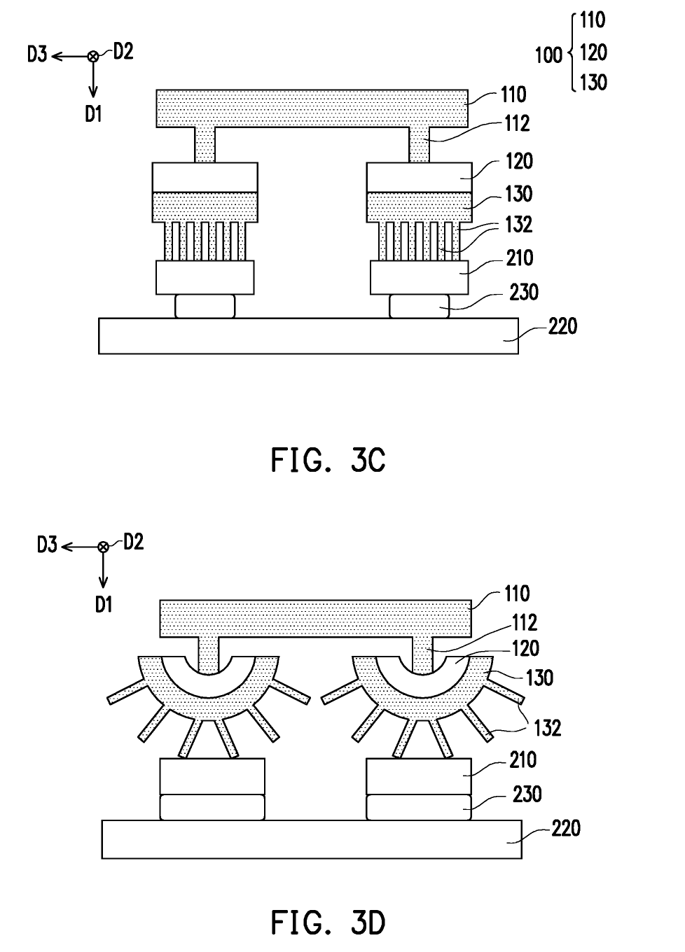

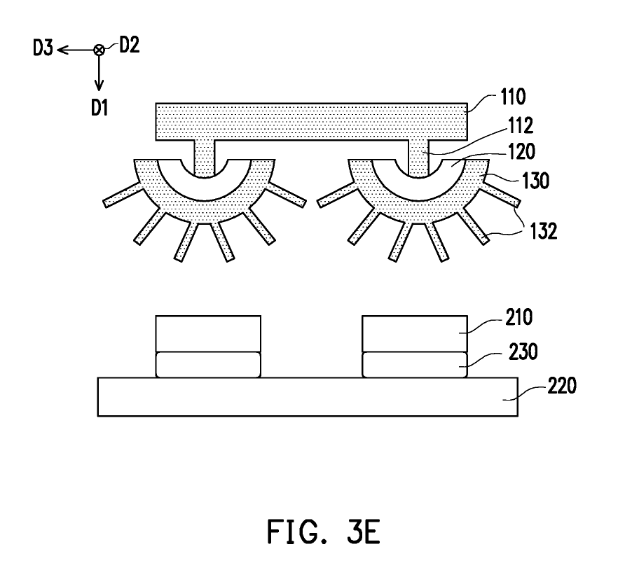

The plurality of transfer heads 130 are respectively disposed on the plurality of deformable components 120. The transfer head 130 includes a plurality of micro protrusions 132 arranged in an array on a side away from the deformable component 120. For example, in the present embodiment, the plurality of micro protrusions 132 may be a plurality of pillars extending towards micro LED dies 210 (illustrated in FIG. 3A) to be transferred, and the plurality of pillars are spaced apart from each other.

FIG. 2 is a top-view schematic diagram illustrating a transfer head according to an embodiment of the invention. Specifically, FIG. 2 is a top-view schematic diagram of the transfer head 130 viewed along an opposite direction of a direction D1 in FIG. 1. Referring to FIG. 1 and FIG. 2, in the present embodiment, the micro protrusion 132 has a diameter D. The micro protrusion 132 extends in the direction D1. Two adjacent micro protrusions 132 have a gap P2 in a direction D2 perpendicular to the direction D1. Two adjacent micro protrusions 132 have a gap P3 in a direction D3 perpendicular to the direction D1 and the direction D2. By adjusting the diameter D, the gap P2, and/or the gap P3 of the micro protrusions 132, a magnitude of pick up force of the transfer head 130 with respect to the micro LED die 210 can be controlled. For example, in an embodiment, the diameter D, the gap P2, and/or the gap P3 of the micro protrusions 132 are respectively 0.05 μm, 0.05 μm, and 0.05 μm, and the transfer head 130 including the plurality of micro protrusions 132 has a capability of picking up the micro LED dies 210 of various sizes. However, the invention is not limited hereto. In other embodiments, the diameter D, the gap P2, and/or the gap P3 may also be other adequate values. In the present embodiment, the transfer head 130 is an elastomer. For example, a material of the transfer head 130 includes polysiloxane, or more specifically, polydimethyl siloxane, but the invention is not limited hereto.

FIG. 3A to FIG. 3E illustrate a process of transferring a plurality of micro LED dies by using a transfer device according to an embodiment of the invention. Referring to FIG. 3A, first, the plurality of transfer heads 130 of the transfer device 100 are aligned with the plurality of micro LED dies 210 located on a die temporary storage substrate 200. Next, the plurality of transfer heads 130 of the transfer device 100 are respectively contacted with the plurality of micro LED dies 210. Referring to FIG. 3B, then, the transfer device 100 is moved away from above the die temporary storage substrate 200. At this time, the transfer heads 130 bring the plurality of micro LED dies 210 away from the die temporary storage substrate 200 through a van der Waals force. Referring to FIG. 3C, next, the transfer device 100 carries the micro LED dies 210 to above a target (e.g., a driving circuit plate 220). Then, the plurality of micro LED dies 210 are respectively aligned and contacted with a plurality of conductive bumps 230 on the driving circuit plate 220.

Referring to FIG. 3D, after the micro LED dies 210 and the conductive bumps 230 are electrically connected, the deformable components 120 are deformed in preparation for releasing the micro LED dies 210. For example, in the present embodiment, the deformable components 120 are heated to cause the deformable components 120 to be deformed and protrude towards the direction D1 away from the carrier plate 110. At this time, the deformable components 120 lead to bending of the transfer heads 130, such that a number of the micro protrusions 132 of the transfer heads 130 in contact with the micro LED dies 210 is decreased to reduce the van der Waals force between the transfer heads 130 and the micro LED dies 210. Referring to FIG. 3E, next, the transfer device 100 is moved away from above the micro LED dies 210. Since the van der Waals force between the transfer heads 130 and the micro LED dies 210 is reduced, the micro LED dies 210 can naturally be successfully released from the transfer heads 130 and left on the target (e.g., the driving circuit plate 220). Accordingly, the micro LED dies 210 can be easily released without precisely controlling a speed of releasing a macromolecular stamp from above the micro LED dies or precisely controlling an evaporation rate of fluid in a manufacturing environment, and thereby the plurality of micro LED dies 210 can be transferred rapidly in large quantities.

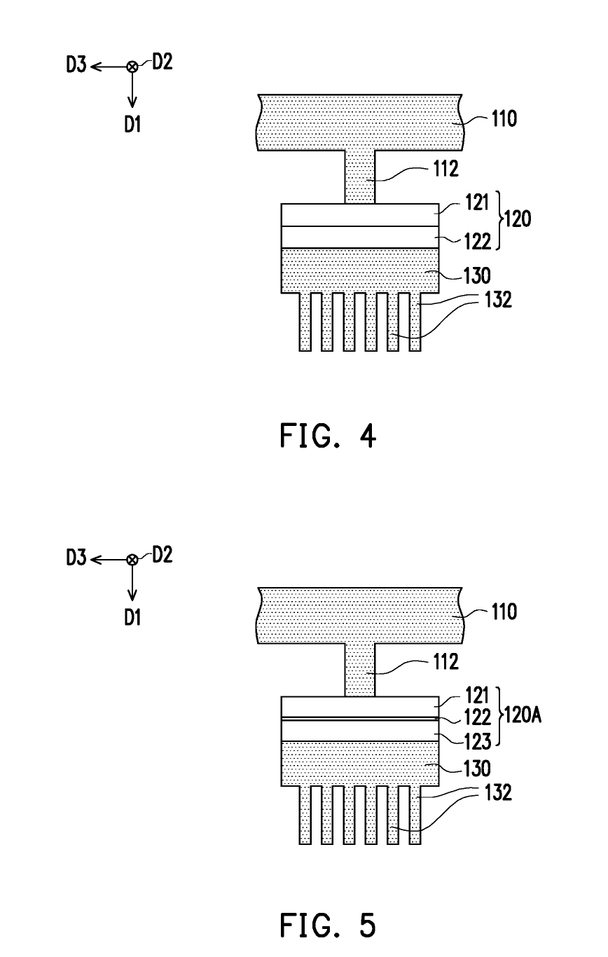

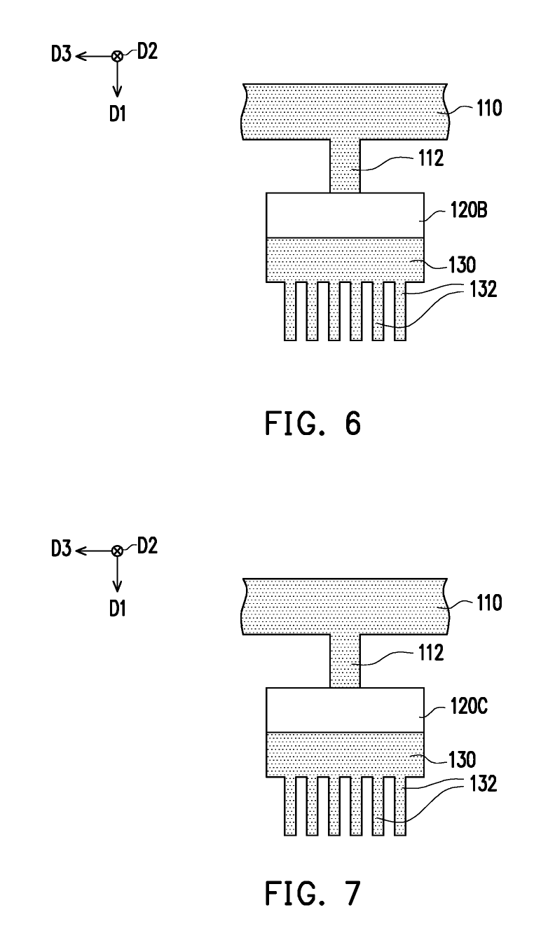

FIG. 4 illustrates a cross-section of a deformable component according to an embodiment of the invention. Referring to FIG. 4, in the present embodiment, the deformable component 120 includes a first material layer 121 disposed on the carrier plate 110 and a second material layer 122 disposed on the first material layer 121. The first material layer 121 is located between the carrier plate 110 and the second material layer 122. The first material layer 121 has a first coefficient of thermal expansion, the second material layer 122 has a second coefficient of thermal expansion, and the second coefficient of thermal expansion is larger than the first coefficient of thermal expansion. Since the coefficients of thermal expansion of the first material layer 121 and the second material layer 122 are different, when the deformable component 120 is heated in the foregoing process of transferring the micro LED die 210, the deformable component 120 protrudes towards the direction D1 away from the carrier plate 110, which thereby causes the transfer head 130 to successfully release the micro LED die 210. For example, in the present embodiment, the first material layer 121 is a titanium layer, and the second material layer 122 is a nickel layer. However, the invention is not limited hereto. In other embodiments, the deformable component 120 may also be present in other suitable configurations, such that a method of deforming the deformable component 120 is not limited to heating. Examples are illustrated below with reference to FIG. 5, FIG. 6, and FIG. 7.

FIG. 5 illustrates a cross-section of a deformable component according to another embodiment of the invention. Referring to FIG. 5, in another embodiment, a deformable component 120A includes a first material layer 121, a second material layer 122, and a third material layer 123 sequentially stacked from the carrier plate 110 to the transfer head 130. The first material layer 121 has a first coefficient of thermal expansion, the second material layer 122 has a second coefficient of thermal expansion, the third material layer 123 has a third coefficient of thermal expansion, the second coefficient of thermal expansion is larger than the first coefficient of thermal expansion and the third coefficient of thermal expansion, and the first coefficient of thermal expansion is equal to the third coefficient of thermal expansion. For example, in the present embodiment, the first material layer 121 is a nickel layer, the second material layer 122 is a titanium layer, and the third material layer 123 is a nickel layer, but the invention is not limited hereto. The deformable component 120A is used to replace the deformable component 120 in FIG. 3A to FIG. 3E. The deformable component 120A is heated and deformed in the foregoing process of transferring the micro LED die 210 to lead to bending of the transfer head 130, which thereby causes the transfer head 130 to successfully release the micro LED die 210.

FIG. 6 illustrates a cross-section of a deformable component according to another embodiment of the invention. Referring to FIG. 6, in another embodiment, a deformable component 120B includes macromolecules having a double-bond structure such as azobenzene group in a molecular structure. The deformable component 120B is used to replace the deformable component 120 in FIG. 3A to FIG. 3E. The deformable component 120B is irradiated by light and deformed in the foregoing process of transferring the micro LED die 210 to lead to bending of the transfer head 130, which thereby causes the transfer head 130 to successfully release the micro LED die 210.

FIG. 7 is a cross-sectional schematic diagram illustrating a deformable component according to another embodiment of the invention. Referring to FIG. 7, in an embodiment, a deformable component 120C includes an alloy formed of at least two metals having different resistivities, e.g., a nickel-titanium alloy having a nickel content of 55-60 wt %. The deformable component 120C is used to replace the deformable component 120 in FIG. 3A to FIG. 3E. The deformable component 120C is applied with a current and deformed in the foregoing process of transferring the micro LED die 210 to thereby cause the transfer head 130 to successfully release the micro LED die 210. In the present embodiment, a material having a smaller resistivity is titanium, for example, and a material having a larger resistivity is nickel. However, the invention is not limited hereto. In other embodiments, other materials may also be adopted to manufacture the deformable component 120C.

In summary of the above, the transfer device of the embodiments of the invention includes the carrier plate, the plurality of deformable components, and the plurality of transfer heads. The plurality of deformable components are disposed on the carrier plate. The plurality of transfer heads are respectively disposed on the plurality of deformable components. Each of the transfer heads includes the plurality of micro protrusions arranged in an array on a side away from the corresponding one deformable component. When the transfer device is to release the micro LED dies, the deformable components are deformed, which leads to bending of the transfer heads, such that the number of the micro protrusions of the transfer heads in contact with the micro LED dies is decreased. When the number of the micro protrusions in contact with the micro LED dies is decreased to the extent that the van der Waals force cannot be sufficiently generated, the transfer heads can easily release the micro LED dies and successfully transfer the micro LED dies onto the target (e.g., the driving circuit plate). Accordingly, a success rate of transferring the micro LED dies is high, and the micro LED dies can be rapidly transferred in large quantities.

Lastly, it shall be noted that the foregoing embodiments are meant to illustrate, rather than limit, the technical solutions of the embodiments of the invention. Although the invention has been detailed with reference to the foregoing embodiments, persons ordinarily skilled in the art shall be aware that they may still make modifications to the technical solutions recited in the foregoing embodiments or make equivalent replacements of part or all of the technical features therein, and these modifications or replacements do not cause the nature of the corresponding technical solutions to depart from the scope of the technical solutions of the embodiments of the invention.

What is claimed is:

1. A transfer device for transferring a plurality of micro LED dies, the transfer device comprising:
a carrier plate;
a plurality of deformable components disposed on the carrier plate; and
a plurality of transfer heads respectively disposed on the plurality of deformable components, wherein each of the transfer heads comprises a plurality of micro protrusions arranged in an array on a side away from the corresponding one deformable component.

2. The transfer device according to claim 1, wherein each of the deformable components is adapted to be deformed due to an influence of light, heat, or electricity, and each of the deformed deformable components protrudes towards a direction away from the carrier plate.

3. The transfer device according to claim 1, wherein each of the deformable components comprises:
a first material layer disposed on the carrier plate and having a first coefficient of thermal expansion; and
a second material layer disposed on the first material layer and having a second coefficient of thermal expansion, wherein the second coefficient of thermal expansion is larger than the first coefficient of thermal expansion.

4. The transfer device according to claim 1, wherein each of the deformable components comprises an alloy formed of at least two metals having different resistivities.

5. The transfer device according to claim 1, wherein each of the deformable components comprises:
a titanium layer disposed on the carrier plate; and
a first nickel layer disposed on the titanium layer.

6. The transfer device according to claim 5, wherein each of the deformable components further comprises:
a second nickel layer, the titanium layer being sandwiched between the first nickel layer and the second nickel layer.

7. The transfer device according to claim 1, wherein the deformable components comprise macromolecules having azobenzene group in a molecular structure.

8. The transfer device according to claim 1, wherein the plurality of micro protrusions comprise a plurality of pillars spaced apart from each other.

9. The transfer device according to claim 1, wherein the carrier plate comprises a plurality of carrying bumps spaced apart from each other, and the plurality of deformable components are respectively disposed on the plurality of carrying bumps.

10. The transfer device according to claim 9, wherein each of the carrying bumps is located within an area of the corresponding one deformable component.
